(19) United States
(12) Patent Application Publication
(10) Pub. No.: US 2025/0224447 A1
(43) Pub. Date: Jul. 10, 2025

(54) DIE-TO-DIE AND CHIP-TO-CHIP INTERCONNECT CLOCK SKEW COMPENSATION

(71) Applicant: PROTEANTECS LTD., Haifa (IL)

(72) Inventors: Eyal FAYNEH, Givatayim (IL); Guy REDLER, Haifa (IL); Yahel DAVID, Kibbutz Gazit (IL); Evelyn LANDMAN, Haifa (IL)

(21) Appl. No.: 18/406,164

(22) Filed: Jan. 7, 2024

(51) Int. Cl. H04J 3/06; H04J 3/14

(52) U.S. Cl. CPC G01R 31/31726; G01R 31/2882; G01R 31/31717; G06F 1/10

(57) ABSTRACT

Die or chip interconnect clock skew compensation can be performed for a multi-IC (Integrated Circuit) module. A timing margin or eye-width parameter (for example, a setup or hold time) for each of one or more interconnect lanes may be measured at a first die or chip of the multi-IC module that is receiving data and clock signals from a second die or chip of the multi-IC module. Compensation information can be determined based on the measured timing margin or eye-width parameter for each of one or more interconnect lanes. Compensation for clock skew can then be based on the determined compensation information.

### FIELD OF THE INVENTION

The invention relates to the field of integrated circuits.

### BACKGROUND

Semiconductor integrated circuits (ICs) typically include analog and digital electronic circuits on a flat semiconductor substrate, such as a silicon wafer. Microscopic transistors are printed onto the substrate using photolithography techniques to produce complex circuits of billions of transistors in a very small area, making modern electronic circuit design using ICs both low cost and high performance. ICs are produced in assembly lines of factories, termed foundries, which have commoditized the production of ICs, such as complementary metal-oxide-semiconductor (CMOS) ICs.

Typically, ICs are produced in large batches on a single wafer of electronic-grade silicon (EGS) or other semiconductor (such as GaAs). The wafer is cut (diced) into many pieces, each containing one copy of the circuit. Each of these pieces is called a ‘die.’

Digital ICs are typically packaged in a metal, plastic, glass, or ceramic casing. The casing, or ‘package,’ is connected to a circuit board, such as by using solder. Types of packages include a lead frame (though-hole, surface mount, chip-carrier, and/or the like), pin grid array, chip scale package, ball grid array, and/or the like, to connect between the IC pads and the circuit board.

Some modern ICs are in fact a module made up of multiple interconnected ICs (sometime referred to as “chips,” “dies,” “tiles,” or “chiplets”) that are configured to cooperate. This may be termed a multi-IC module. A typical example is a logic IC interconnected with a memory IC, but many other types exist. There are also many die-to-die (namely, IC-to-IC) connectivity technologies in existence. One example is wafer-level integration featuring high-density connectivity, that is based on a Re-Distribution Layer (RDL) and Through Integrated Fan-Out Vias (TIVs), for instance as marketed by Taiwan Semiconductor Manufacturing Company (TSMC), Limited. Another example is system-level integration featuring individual chips bonded through micro-bumps on a silicon interposer, for instance the Chip on Wafer on Substrate (CoWoS) technology marketed by TSMC Limited, and the Embedded Interconnect Bridge (EMIB) technology marketed by Intel Corporation. Both enable High Bandwidth Memory (HBM) subsystems. A third example is three-dimensional (3D) chip stacking technology based on Through Silicon Vias (TSVs), for instance the Chip on Wafer (CoW) and Wafer on Wafer (WoW) technologies marketed by TSMC Limited.

The foregoing examples of the related art and limitations related therewith are intended to be illustrative and not exclusive. Other limitations of the related art will become apparent to those of skill in the art upon a reading of the specification and a study of the figures.

### SUMMARY

The following embodiments and aspects thereof are described and illustrated in conjunction with systems, tools and methods which are meant to be exemplary and illustrative, not limiting in scope.

In a first aspect, there is provided a method of die or chip (continuous, for example at a low frequency variation over time) interconnect clock skew compensation for a multi-IC (Integrated Circuit) module. The method comprises: measuring a timing margin or eye-width parameter for each of one or more interconnect lanes at a first die or chip of the multi-IC module that is receiving data and clock signals from a second die or chip of the multi-IC module; determining compensation information based on the measured timing margin or eye-width parameter for each of one or more interconnect lanes; and compensating for clock skew based on the determined compensation information.

In embodiments, the method further comprises: communicating the determined compensation information from the first die or chip of the multi-IC module to the second die or chip of the multi-IC module. In embodiments, the step of compensating is performed at the second die or chip of the multi-IC module.

In embodiments, the step of measuring a timing margin or eye-width parameter for each of the one or more interconnect lanes comprises: testing a time span for the timing margin or eye-width parameter of the respective interconnect lane; and outputting a test fail signal for the respective interconnect lane, the test fail signal being indicative of whether the timing margin or eye-width parameter is greater than or less than the time span.

In embodiments, the step of testing a time span for the timing margin or eye-width parameter of the respective interconnect lane comprises: setting an adjustable delay-line to delay by the time span, applying the set adjustable delay-line to a signal from the respective interconnect lane to generate a delayed interconnect lane signal, sampling the delayed interconnect lane signal and the signal from the respective interconnect lane with the same clock signal and comparing the sampled delayed interconnect lane signal with the sampled signal from the respective interconnect lane, the outputted test fail signal being based on a result of the comparing.

In embodiments, the steps of testing and outputting are repeated for multiple different time spans.

In embodiments, the one or more interconnect lanes comprise a plurality of interconnect lanes and the step of determining compensation information is based on measured timing margins or eye-width parameters for the plurality of interconnect lanes.

In embodiments, the step of determining compensation information comprises: calculating an average for the timing margin or eye-width parameter over the plurality of interconnect lanes, the compensation information being based on the average for the timing margin or eye-width parameter.

In embodiments, the average for the timing margin or eye-width parameter is calculated by taking half of the sum of a maximum of the measured timing margins or eye-width parameters and a minimum of the measured timing margins or eye-width parameters.

In embodiments, the step of determining compensation information further comprises: calculating a difference between a maximum of the measured setup times and a minimum of the measured setup times, the step of calculating an average setup time being performed if the difference is no greater than a threshold.

In embodiments, the timing margin is a setup time or a hold time.

In embodiments, the step of determining compensation information is based on temperature information for the multi-IC module and/or voltage information for the multi-IC module.

In embodiments, the compensation information comprises a timing shift to be applied to a clock signal associated with the respective interconnect lane.

In embodiments, the timing shift is applied to a reference clock associated with the one or more interconnect lanes.

In embodiments, the step of determining compensation information comprises: calculating an average for the timing margin or eye-width parameter over the plurality of interconnect lanes, the compensation information being based on the average for the timing margin or eye-width parameter, the timing shift being determined by subtracting the average setup time from a reference position of the reference clock.

In another aspect, there is provided a system for die or chip interconnect clock skew compensation for a multi-IC (Integrated Circuit) module. The system comprises: at least one Input/Output (I/O) sensor, each I/O sensor being configured to measure a respective one of one or more interconnect lanes at a first die or chip of the multi-IC module that is receiving data and clock signals from a second die or chip of the multi-IC module; a controller, configured to determine a respective timing margin or eye-width parameter for each of the one or more interconnect lanes based on the measurement of the respective I/O sensor and to determine compensation information to compensate for clock skew based on the timing margin or eye-width parameter for each of the one or more interconnect lanes.

In embodiments, the controller is further configured to communicate the determined compensation information from to the second die or chip of the multi-IC module, such that compensation for clock skew can be performed at the second die or chip of the multi-IC module, based on the determined compensation information.

In embodiments, each I/O sensor is configured to measure the respective one of the one or more interconnect lanes by: testing a time span for the timing margin or eye-width parameter of the respective interconnect lane; and outputting a test fail signal for the respective interconnect lane, the test fail signal being indicative of whether the timing margin or eye-width parameter is greater than or less than the time span.

In embodiments, each I/O sensor comprises: an adjustable delay-line, configured to apply the time span to a signal from the respective interconnect lane to generate a delayed interconnect lane signal; at least one state element, configured to sample the delayed interconnect lane signal and the signal from the respective interconnect lane with the same clock signal; and a comparison circuit, configured to compare the sampled delayed interconnect lane signal with the sampled signal from the respective interconnect lane and output the test fail signal based on a result of the comparing.

In embodiments, the controller is configured to cause each I/O sensor to repeat the testing and outputting for multiple different time spans in order to determine the respective timing margin or eye-width parameter for each of the one or more interconnect lanes.

In embodiments, the one or more interconnect lanes comprise a plurality of interconnect lanes and the controller is configured to determine the compensation information based on the timing margins or eye-width parameters for the plurality of interconnect lanes.

In embodiments, the controller is configured to determine the compensation information by calculating an average for the timing margin or eye-width parameter over the plurality of interconnect lanes, the compensation information being based on the average for the timing margin or eye-width parameter.

In embodiments, the controller is configured to calculate the average for the timing margin or eye-width parameter by taking half of the sum of a maximum of the measured timing margins or eye-width parameters and a minimum of the measured timing margins or eye-width parameters.

In embodiments, the controller is configured to determine the compensation information by calculating a difference between a maximum of the measured timing margins or eye-width parameters and a minimum of the measured timing margins or eye-width parameters, the average for the timing margin or eye-width parameter being calculated if the difference is no greater than a threshold.

In embodiments, the controller is configured to receive temperature information for the multi-IC module and/or voltage information for the multi-IC module and to determine the compensation information based on the received temperature information and/or the received voltage information.

In embodiments, the controller is configured to determine the compensation information as a timing shift to be applied to a clock signal associated with the respective interconnect lane.

In embodiments, the controller is configured to determine the timing shift to be applied to a reference clock associated with the respective interconnect lane.

In embodiments, the controller is further configured to determine the compensation information by calculating an average for the timing margin or eye-width parameter over the plurality of interconnect lanes, the compensation information being based on the average for the timing margin or eye-width parameter, the timing shift being determined by subtracting the average for the timing margin or eye-width parameter from a reference position of the reference clock.

In a further embodiment, there is provided a multi-IC (Integrated Circuit) module comprising: a first die or chip, configured to receive data and clock signals over one or more interconnect lanes; a second die or chip, configured to transmit the data and clock signals over the one or more interconnect lanes to the first die or chip; a system for die or chip interconnect clock skew compensation as described herein, coupled to the first die or chip and configured to compensate for clock skew in the clock signals.

In yet another embodiments, there is provided a non-transitory computer readable medium having stored thereon a computer-readable encoding of a system for die or chip interconnect clock skew compensation for a multi-IC (Integrated Circuit) module, the system comprising: at least one Input/Output (I/O) sensor, each I/O sensor being configured to measure a respective one of one or more interconnect lanes at a first die or chip of the multi-IC module that is receiving data and clock signals from a second die or chip of the multi-IC module; a controller, configured to determine a respective timing margin or eye-width parameter for each of the one or more interconnect lanes based on the measurement of the respective I/O sensor and to determine compensation information to compensate for clock skew based on the timing margin or eye-width parameter for each of the one or more interconnect lanes.

In addition to the exemplary aspects and embodiments described above, further aspects and embodiments will become apparent by reference to the figures and by study of the following detailed description. The skilled person will appreciate that combinations and sub-combinations of specific features disclosed herein may also be provided, even if not explicitly described.

### BRIEF DESCRIPTION OF THE FIGURES

Exemplary embodiments are illustrated in referenced figures. Dimensions of components and features shown in the figures are generally chosen for convenience and clarity of presentation and are not necessarily shown to scale. The figures are listed below.

FIG. 1 shows a schematic block diagram of a chip-or-chip or die-to-die connectivity configuration in a multi-IC module in line with the specification released by the Universal Chiplet Interconnect Express (UCIe) Consortium, discussed further below.

FIG. 2 shows a schematic block diagram of an example system for die or chip interconnect clock skew compensation for a multi-IC module according to the disclosure.

FIG. 3 shows a schematic block diagram of an example controller forming part of a system in accordance with FIG. 2.

FIG. 4 shows a flowchart for an example process of die or chip interconnect clock skew compensation for a multi-IC module according to the disclosure.

### DETAILED DESCRIPTION

Disclosed herein are devices, systems, and methods to measure and/or to compensate die or chip interconnect clock skew for a multi-IC module.

The term ‘multi-IC module,’ as referred to herein, may describe a group of interconnected ICs that are integrated and packaged together, and are configured to cooperate through this interconnection in order to achieve a certain joint functionality. The ICs in the module may communicate with each other through an interconnect bus (sometimes also called simply an “interconnect,” a “lane,” or “a channel”), for example. Their physical integration may be horizontal, vertical, or both.

The multi-IC module to which this disclosure relates may be constructed by any known or later introduced integration technology, which either provides for direct connection between ICs, or indirect connection through an intermediary such as a certain interposer, substrate, circuit board, and/or the like. It is also possible for a multi-IC module to employ both direct and indirect connectivity between various pairs of its integrated ICs. Examples of today's multi-IC module integration technologies include Chip on Wafer on Substrate (CoWoS), Wafer On Wafer (WoW), Chip On Wafer (CoW), and 3D IC. However, embodiments of the invention are certainly beneficial also for any other type of multi-IC module which feature die-to-die (IC-to-IC) connectivity or chip-to-chip (C2C) connectivity.

C2C connectivity may be different from die-to-die connectivity. In C2C interconnects, the capacitance may be significantly higher than in other multi-IC module integration technologies due to higher lane length. To reduce any speed limitations on the interconnect, encoding of the data transmitted over the interconnect channel may be implemented (error control or channel coding). Specific encoding patterns may thus be used in calibration of the interconnect. The same or similar patterns may be employed for I/O monitoring. The I/O monitoring may be enabled during the lane training phase at a pre-defined data-rate.

Despite the use of the terms D2D and C2C along this description, those of skill in the art will recognize that embodiments described as useful for D2D may be also useful for C2C, and vice versa.

PCT International Patent Application Publication No. WO2021/214562, incorporated herein by reference, discloses an Input/Output (I/O) sensor for a multi-IC module. The I/O sensor disclosed in this document comprises: delay circuitry, configured to receive a data signal from an interconnected part of an IC of the multi-IC module and to generate a delayed data signal, the delay circuitry comprising an adjustable delay-line configured to delay an input signal by a set time duration (time span); a comparison circuit, configured to generate a comparison signal by comparing the data signal with the delayed data signal; and processing logic, configured to set the time duration of the adjustable delay-line and, based on the comparison signal, identify a margin measurement of the data signal for determining an interconnect quality parameter. The data signal and delayed data signal are both sampled with the same clock signal (typically at a positive edge of the clock signal associated with the data signal), the comparing being performed on the sampled signals. In this way, the margin measurement may be a data signal setup time to clock rising edge, which may be more generally termed a setup time. U.S. Pat. No. 11,815,551, incorporated herein by reference, discloses further I/O sensors for die-to-die connectivity monitoring based on similar approaches. PCT International Patent Application Publication No. WO2020/141516, incorporated herein by reference, also discloses I/O sensors for connectivity monitoring that may be suitable for die-to-die interconnections.

According to this approach, the margin need not be measured by looking at timing differences between signals, but instead by comparing a received data signal with that data signal delayed using an adjustable delay-line set to provide a predetermined time delay. If the comparison results in a pass, the margin is higher than the delay applied to the data signal. Changing the adjustable delay-line time duration (time span) over a range of multiple different values and measuring the comparison for each time span value allows a margin (for instance, the data signal setup time) to be measured. The minimum delay applied to the data signal that causes the comparison to result in a fail may be considered the margin. Using an adjustable delay-line in this way allows high resolution to be achieved on the margin measurement. In contrast, resolution of around 1-2 ps (fraction of a buffer delay) may be achieved using techniques according to the disclosure.

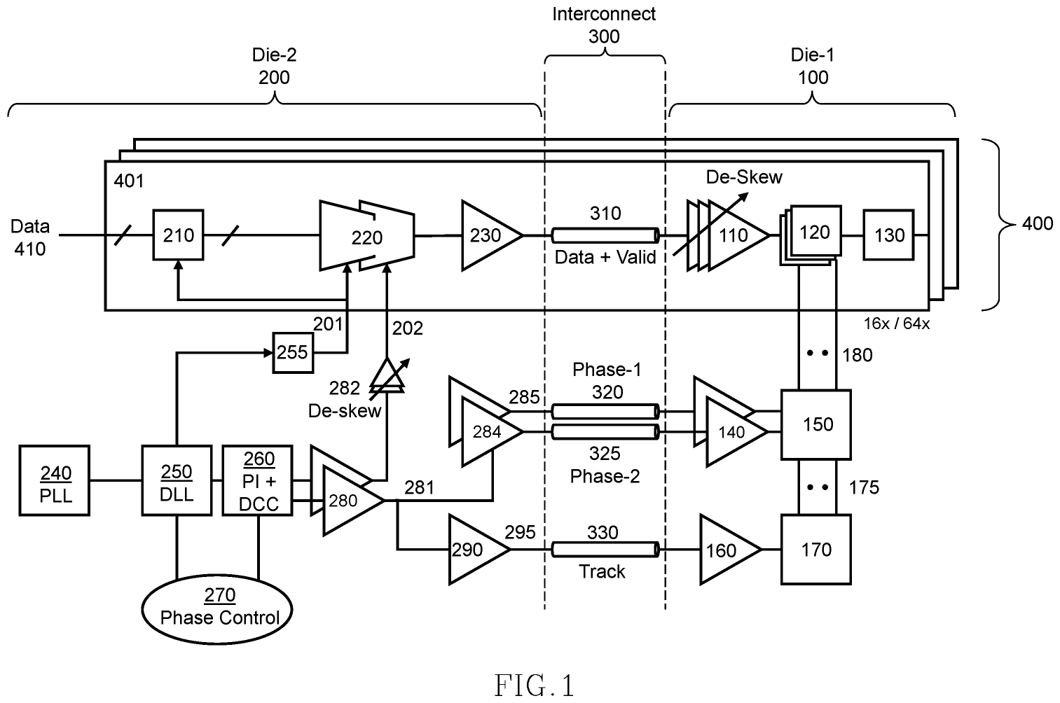

Reference is made to FIG. 1, which depicts a schematic block diagram of a chip-or-chip or die-to-die connectivity configuration in a multi-IC module. This configuration is based on that shown in FIG. 82 of Revision 1.0 of the Universal Chiplet Interconnect Express (UCIe) specification released by the UCIe Consortium on Feb. 24, 2022. Although approaches according to the present disclosure are not limited to this configuration, they may be advantageously applied to such configurations and the configuration may help to understand approaches according to the disclosure better.

The configuration comprises: a first die 100; a second die 200; and an interconnect 300, which together define a plurality of interconnect lanes 400, only a first interconnect lane 401 of which is shown. The first interconnect lane 400 receives data 410 for transmission from the second die 200 to the first die 100. The data 410 passes through a transmission First-In-First-Out (FIFO) buffer 210, serializer 220 and transmitter (TX) 230 in the second die 200, across first interconnections 310 (as data and validity bits) and through a receiver 110, state elements (flip-flops) 120 and a reception FIFO buffer 130.

The transmission FIFO buffer 210 and serializer 220 are controlled by a first transmission clock signal 201. The first transmission clock signal 201 is generated using: a Phase Locked Loop (PLL) 240, which provides a clock signal to a Delay Locked Loop (DLL) 250. The DLL 250 provides two outputs: to a divide-by-N block 255, which generates the first transmission clock signal 201; and to a Phase Interpolator (PI) and Duty Cycle Correction (DCC) circuit 260, both of which are controlled by a phase control block 270. Outputs from the PI and DCC circuit 260 are passed to: de-skew circuit 282, which generates a second transmission clock signal 202 for the serializer 220; clock buffers 284, which generate differential clock signals 285; and a track signal transmitter 290, which generates a track signal 295. The DLL 250 generates clock phases and the phase control block 270 selects the phase to use with the serializer 220. The DCC 260 then generates four clock phases with high accuracy.

The differential clock signals 285 have different phases and are transmitted from the second die 200 to the first die 100 via first clock interconnect 320 and second clock interconnect 325. The track signal 295 is transmitted from the second die 200 to the first die 100 via track signal interconnect 330.

At the first die 100, the differential clock signals 285 are received at clock receivers 140, where they are passed to a phase generator circuit 150. The track signal 295 is received from the track signal interconnect 330 at a track signal receiver 160, where it is passed to a track process block 170, which generates a track control signal to control the phase generator circuit 150, beneficially to compensate for low-frequency changes in the system that manifest in the clock signal phase. Then, the phase generator circuit 150 can generate a receiver clock 180, which may have 2 or 4 phases and is used to clock the flip-flops 120 at the first die 100.

The clock receivers 140 and phase generator circuit 150 regenerate the clock from the differential clock signals 285. For example, to generate a Quad Data Rate (QDR) clock for 32 Giga Transfers (GT) per second, a 8 GHz quadrature clock signal 285 is used, regenerated with four phases. It is known that certain factors, for example, temperature, voltage, may cause the data lane signal to shift with respect to the clock. This is known as low-frequency clock skew, which are dynamic changes occurring during normal operation and come into effect after a lane was trained and an initial clock phase set. Other changes (which may be described as static changes, for example aging) may be compensated by the training process, each time the system is re-started. The receiver flip-flops 120 typically have a short aperture setup time, for instance around 15 picoseconds (ps). The intent of this approach is to perform ongoing de-skewing at the transmitter, which in this case is the second die 200. Such compensation is typically performed at a low frequency (in comparison with a frequency of the clock signal). A shift is applied to the clock at the transmitter and the track signal 295 allows the receiver to reverse the shift (runtime compensation) when generating the receiver clock 180.

According to this approach, the track process block 170 generates a compensation signal from the received track signal 295. This is not straightforward. Moreover, it would be disadvantageous to include a further PI circuit at the first die 100, which is complex to add and will have an impact on link performance.

A different approach is suggested in accordance with this disclosure. It has been recognized that clock skew is correlated with timing margin at the receiver flip-flop. As the clock skew changes, the timing margin changes. The timing margin can be measured at the receiver (first die 100) and based on this, compensation information can be determined and communicated to the transmitter (second die 200). For example, this may be possible using a side-band bus, which is available in the aforementioned UCIe specification (see FIG. 72 thereof). At the transmitter (second die 200), this information can be used by the de-skew circuit 282 to adjust the clock (for example, as discussed in the UCIe specification and known to persons of skill in the art). Setup time is particularly used as a timing margin in this disclosure, but hold time could additionally or alternatively be used and/or an eye width parameter can provide equivalent information.

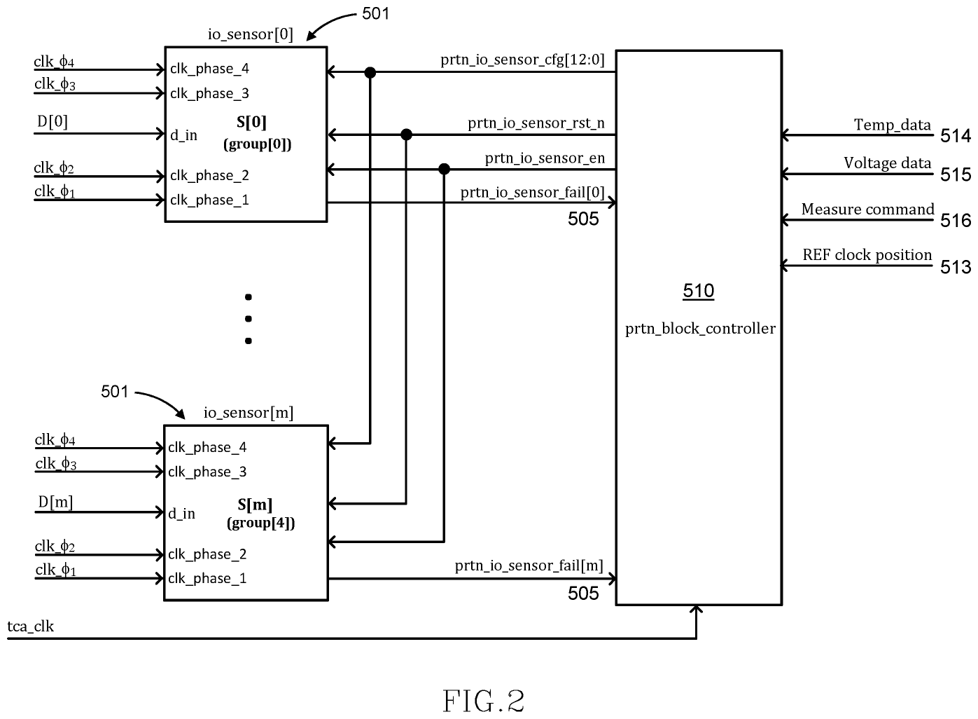

Referring now to FIG. 2, there is shown a schematic block diagram of an example system for die or chip interconnect clock skew compensation for a multi-IC module, according to this disclosure. This system comprises: a plurality of I/O sensors 501 (which may equivalently each be termed a Tile Connectivity Agent or TCA); and a controller 510. Each I/O sensor 501 receives four-phase clock signals (Clk_Ω1, Clk_Ω2, Clk_Ω3, Clk_Ω4) and a Data signal for the mth interconnect lane (D[m]), assuming m I/O sensors 501. The controller 510 provides each I/O sensor 501 with: a configuration signal (ptrn_io_sensor_cfg[12:0]), which configures a delay applied by the respective I/O sensor 501; an enable signal (ptrn_io_sensor_en), which enables or disables the respective I/O sensor 501; and a reset signal (ptrn_io_sensor_rst_n), which resets the respective I/O sensor 501. Each I/O sensor 501 outputs a respective test fail signal 505 (ptrn_io_sensor_fail[0], . . . ptrn_io_sensor_fail[m]) to the controller 510, which indicates whether the setup time is greater than the delay applied by the respective I/O sensor 501 (as set by the configuration signal).

The details of sensors that are suitable for making this determination are described in the two PCT publications and the U.S. patent discussed above, so this information will not be repeated herein. While one or more of the sensors disclosed in these publications expressly show only single phase or two-phase clocks, it will be readily understood that such sensors can also be used for making determinations in relation to other multi-phase clocks (such as the four phase clock of the embodiment of FIG. 2 of this disclosure, or clocks with a higher number of phases) by appropriate selection of clock phase, for example by use of a multiplexer arrangement at the clock input of the sensor.

The controller 510 may also receive temperature data (temp_data) 514 and voltage data 515 for the multi-IC module. In response to receiving a Measure command signal 516, the controller 510 uses the test fail signals from the I/O sensors 501, optionally together with the received temperature data and voltage data (and typically a reference clock position 513, which will be discussed further below) to determine a clock skew compensation.

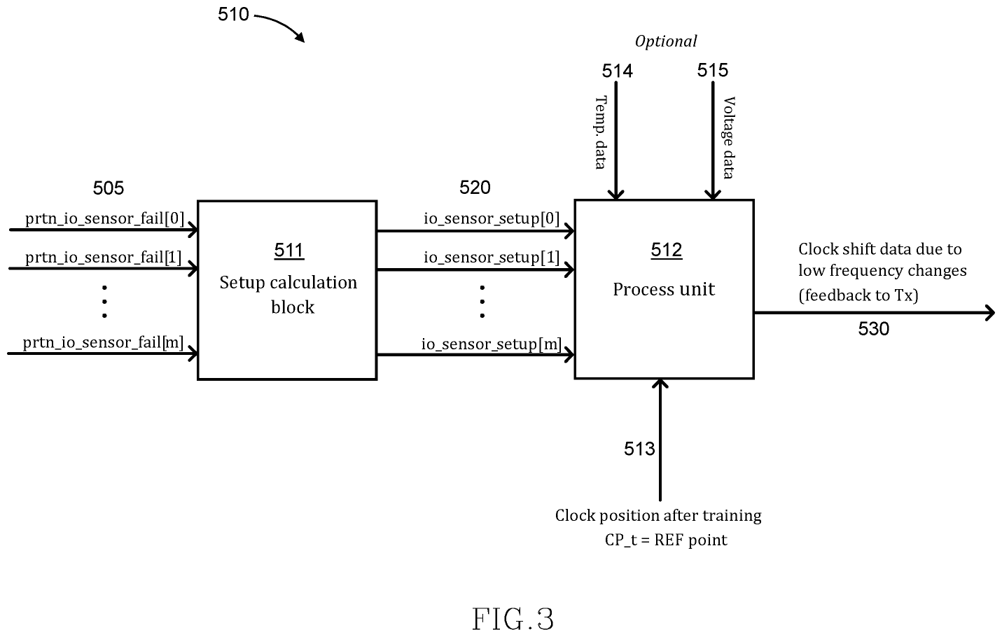

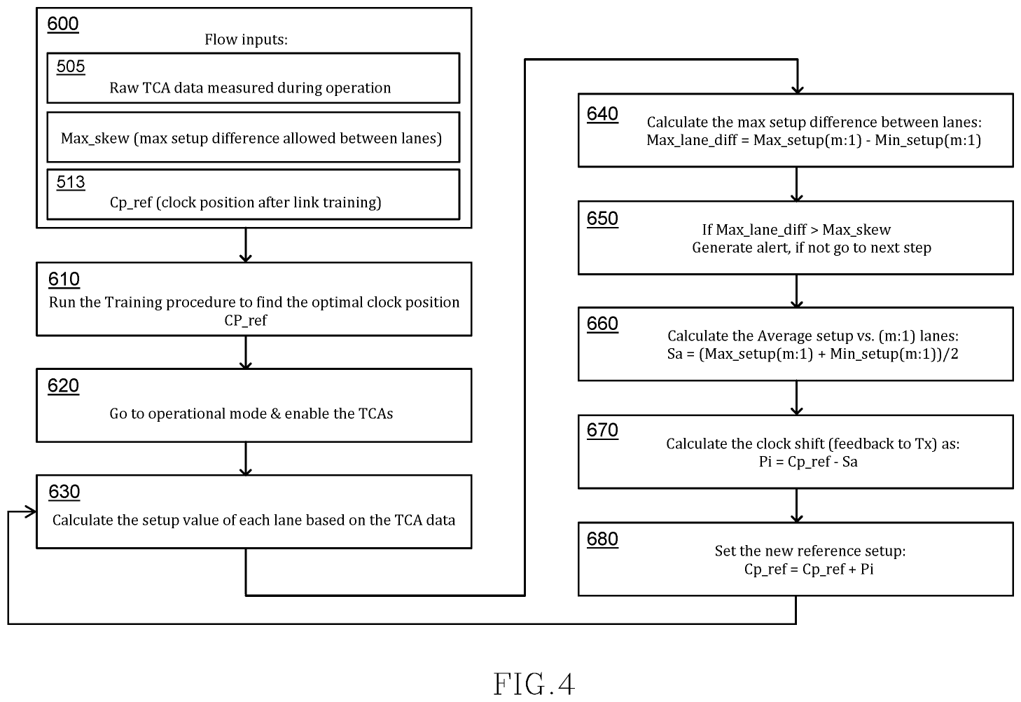

Referring now to FIG. 3, there is shown a schematic block diagram of an example controller 510 forming part of a system in accordance with FIG. 2. The controller 510 notionally comprises two parts: a setup calculation block 511; and a process unit 512. The setup calculation block 511 determines, based on the test fail signals 505 from the I/O sensors 501, a setup time measurement for the respective interconnect lane measured by each I/O sensor. In other words, the timing margin for each interconnect lane is thereby measured. This can be achieved by varying the delay applied to each sensor to determine a lower bound for the setup time (the maximum delay applied for which there is no fail condition) and an upper bound for the setup time (the minimum delay applied for which there is a fail condition), as indicated by the test fail signal from the I/O sensor. Based on the determined lower bound and upper bound, a setup time 520 for each sensor is established (io_sensor_setup[0], io_sensor_setup[1], . . . io_sensor_setup[m]) and this is communicated to the process unit 512. The process unit 512 also receives a clock position 513, which indicates a position of a reference clock after training. This will be discussed further with reference to FIG. 4 below. The process unit 512 may also receive temperature data 514 and voltage data 515, as discussed with reference to FIG. 2 above.

The process unit 512 uses the clock position 513 and the established setup times 520 for the sensors, optionally together with the received temperature data 514 and voltage data 515, to determine compensation information in the form of a clock shift 530. The clock shift 530 indicates a shift to be applied to a reference clock for use in de-skewing at the transmitter (as detailed with reference to FIG. 1 above). As it can be seen from FIG. 1, a group of interconnect lanes 400 comprises lanes 401 made up from identical circuits. Each circuit comprises electrical components (mainly transistors) that are sensitive to voltage and temperature. For example, the transistor current changes with temperature and voltage. Specifically in a MOSFET, I_{D}=Kx(Vgs−Vth)², where ID represents the drain current, Vgs is the gate-source voltage, Vth is the threshold voltage and Kx is a constant. It is well known that the threshold voltage Vth changes with temperature. The interconnect by itself may also have temperature dependent parameters.

Referring next to FIG. 4, there is shown a flowchart for an example process (method) of die or chip interconnect clock skew compensation for a multi-IC module according to the disclosure. This process is typically implemented at the controller 510 of the system. Inputs 600 comprise: test fail signals 505 from the I/O sensors 501 (also termed TCAs); a configuration parameter, which defines a maximum setup time difference allowed between interconnect lanes (Max_skew, not numbered); and the clock position 513 determined after training (which will be discussed further below). The test fail signals 505 are termed “raw TCA data”, because no analysis of this data to determine setup times has been performed. Rather, the setup times 520 are calculated based on the test fail signals 505 provided directly to the controller 510 from the individual I/O sensors 501.

A first step 610 relates to the determination of the clock position 513 discussed above. Before normal operation of the multi-IC module (for example, upon powering up), a clock training procedure is initialized (for example, by the controller 510). This training procedure determines an optimal timing position 513 for the clock determined in the training or system-initialization, which is labelled CP_ref. This does not represent a position of the clock used in operation, which may have a timing that differs from that defined by CP_ref (in particular, due to low-frequency changes occurring after training is complete).

In a second step 620, the normal operation of the multi-IC module is started. The I/O sensors 501 (TCAs) begin measuring each interconnect lane during this normal operation and determine test fail signals 505. These are beneficially communicated from each I/O sensor 501 (TCA) to the controller 510.

In a third step 630, the test fail signals 505 are used to calculate (establish) setup times 520 for each interconnect lane (at the controller 510). As indicated above, the test fail signals 505 may indicate lower and upper bounds for each setup time, but a single setup time is advantageously established for each interconnect lane (for example, by taking a mid-point or some other figure of merit value based on the indicated lower and upper bounds). The result of the third step 630 is therefore a plurality of setup times, each setup time corresponding with a respective interconnect lane.

In a fourth step 640, the range of the established setup times is identified. This range (Max_lane_diff) is the difference between the maximum setup time from the plurality of setup times and the minimum setup time from the plurality of setup times, which can be represented as Max_lane_diff=Max_setup (m:1)−Min_setup (m:1).

A fifth step 650 then determines if the range of the established setup times (Max_lane_diff) is greater than the configuration parameter that defines the maximum setup time difference allowed between interconnect lanes (Max_skew). If so, an alert is generated and the process is terminated pending external input. Otherwise, the method proceeds to the sixth step 660. Checking the range against a threshold is useful in this case, because the system uses data from a group of lanes to determine the compensation for low-frequency changes. Such low-frequency changes may include dynamic (or AC) changes in the skew of all the lanes in the group with respect to a common clock, for example due to changes temperature changes that will affect all the lanes in the group in the same direction and amplitude. The calculated compensation should fit all the lanes. This may not be possible if the inherent (static or DC) skew between the lanes is above a certain amplitude. The inherent DC skew between the lanes should be compensated per lane at time zero as part of the training process, as discussed above. If the range is higher than the allowed amount, this may indicate failure in the training process.

In the sixth step 660, an average setup time across the lanes is determined. In this embodiment, the average setup time is calculated based only on the maximum setup time from the plurality of setup times and the minimum setup time from the plurality of setup times. In other words, the average setup time is calculated by summing the maximum setup time from the plurality of setup times and the minimum setup time from the plurality of setup times and dividing that total by two. It will be appreciated that other averages (or different statistical parameters) of the measured setup times can be calculated and then used in other embodiments.

The seventh step 670 calculates the clock shift to be applied for de-skewing, Pi. This is determined by subtracting the average setup time from the reference clock position 513, Cp_ref. According to the embodiment as described in FIGS. 1 to 3 above, this is now communicated to the transmitter for de-skewing the clock there.

In an eighth step 680, the reference clock position 513, Cp_ref, is updated. This is achieved by adding the clock shift to be applied for de-skewing, Pi, to the current reference clock position Cp_ref, to create a new reference clock position 513, Cp_ref. The process then returns to the third step 630 where it repeats using the new reference clock position 513, Cp_ref. This process is advantageously performed at the second (transmitting) die 200, for example at the de-skew circuit 282.

It will be understood that the fourth step 640, fifth step 650 and sixth step 660 are optional and/or can be varied. Similarly, the seventh step 670 can be achieved in a different way, for example using one or more determined setup times directly to calculate the clock shift. The eighth step 680 can also be varied accordingly.

As discussed above, temperature and/or voltage information can also be used for determining compensation information. It is noted that, in the implementation described above, the TCA measures discrete options for the setup time (in particular, because an adjustable delay line in the TCA can apply discrete delays), typically with step-size intervals between these discrete options. As a result, the controller calculates the average setup time based on the TCA discrete options. Before the calculated clock shift is used in the second die 200, it is advantageously translated to one of the discrete options of the second die de-skew circuit 282, which may have different discrete options (for example, a different step size). The controller is provided with a conversion factor between the TCA discrete options (step size) and the discrete options (step size) of the de-skew circuit 282. For example, if the TCA step at a certain temperature and voltage (To, Vo) is 2 ps and the step size of the de-skew circuit 282 is 1 ps at the same temperature and voltage (To, Vo), then the conversion factor is 2. In other words, each change of a step in the TCA step is equal a change of two steps (in the same direction) in the de-skew circuit 282.

Also, if there is a voltage difference between the first die 100 (transmitter side) and the second die 200 (receiver side), the conversion factor should be compensated. For example, if the voltage at the first die 100 (transmitter side) is lower by 10% relative to the voltage at the second die 200 (receiver side), the de-skew delay step is higher by 10%. Consequently (assuming a linear voltage-to-delay behavior), the compensated conversion ratio that will be calculated by the controller is: [1/0.9]=1.1. It should be noted that the relationship between voltage and delay may not be linear and any function could be used for this relationship according to the specific implementation.

In general, the first and second dies are very close and powered by the same power supply, so we can assume that the temperature and voltage of TCA and the de-skew circuit 282 are close enough to be the same for practical purposes. Practically, a delay provided by the de-skew circuit 282 may be implemented with a delay-line in the TCA (in other words, using the same circuit). Moreover, the TCA and the de-skew circuit 282 are typically be powered by the same VDD core, which is a different supply than the main transmitter die supply (VDDQL), driving the transmission buffers. As a result, the voltage should be stable and the voltage difference should be minimal. In that case, any temperature difference has less effect. Nevertheless, if the local temperature or voltage of the TCA is different than the local temperature or voltage of the de-skew circuit 282, knowing the voltages and/or temperatures (and/or their relative levels) may help to make the conversion factor more accurate and this can be accounted by a factor in the conversion.

In a general sense, there may be considered a method of and/or system for die or chip interconnect clock skew compensation for a multi-IC module. A timing margin or eye-width parameter is measured for each of one or more interconnect lanes at a first (Rx) die or chip of the multi-IC module that is receiving data and clock signals from a second die or chip of the multi-IC module. For example, the timing margin may comprise a setup time and/or a hold time. Each interconnect lane may be measured by a respective Input/Output (I/O) sensor. Compensation information is then determined (for instance, by a controller) based on the measured timing margin or eye-width parameter for each of one or more interconnect lanes. Advantageously, compensation for clock skew can then be based on the determined compensation information. The controller may also perform such compensation.

There may also be considered a multi-IC (Integrated Circuit) module comprising: a first die or chip, configured to receive data and clock signals over one or more interconnect lanes; a second die or chip, configured to transmit the data and clock signals over the one or more interconnect lanes to the first die or chip; and a system for die or chip interconnect clock skew compensation as described herein, coupled to the first die or chip and configured to compensate for clock skew in the clock signals.

Various features may be applied to any aspect as herein disclosed, some of which will now be discussed.

The determined compensation information may be communicated (by the controller) from the first die or chip of the multi-IC module to the second die or chip of the multi-IC module. Then, the compensation can be performed at the second die or chip of the multi-IC module (that is, at the transmitter). This may apply for a multi-IC module in line with the UCIe specification, when the compensation is performed at the second die or chip. However, communication of the compensation information from the first die or chip to the second die or chip but also more generally take place even if compensation is performed at the first die or chip.

The timing margin or eye-width parameter for each of the one or more interconnect lanes may be measured (at each I/O sensor) by: testing a time span for the timing margin or eye-width parameter of the respective interconnect lane; and outputting a test fail signal for the respective interconnect lane. The test fail signal is beneficially indicative of whether the timing margin or eye-width parameter is greater than or less than the time span.

The time span for the timing margin or eye-width parameter of the respective interconnect lane may be tested by: setting an adjustable delay-line (of the respective I/O sensor) to delay by the time span, applying the set adjustable delay-line to a signal from the respective interconnect lane to generate a delayed interconnect lane signal, sampling (by at least one state element) the delayed interconnect lane signal and the signal from the respective interconnect lane with the same clock signal and comparing (using a comparison circuit) the sampled delayed interconnect lane signal with the sampled signal from the respective interconnect lane. The outputted test fail signal (from the comparison circuit) may then be based on a result of the comparing.

Optionally, the testing and outputting are repeated (by the controller) for multiple different time spans. This may allow determination of the respective timing margin or eye-width parameter for each of the one or more interconnect lanes. This is not strictly necessary, however. In some cases, the same time span may be measured repeatedly.

The one or more interconnect lanes may comprise a plurality of interconnect lanes. Then, the compensation information may be determined (by the controller) based on measured timing margins or eye-width parameters for the plurality of interconnect lanes.

The compensation information may be determined (by the controller) by calculating an average for the timing margin or eye-width parameter over the plurality of interconnect lanes. Then, the compensation information may be based on the average for the timing margin or eye-width parameter. The average for the timing margin or eye-width parameter may be calculated by taking half of the sum of a maximum of the measured timing margins or eye-width parameters and a minimum of the measured timing margins or eye-width parameters. Optionally, as part of the compensation information determination, a difference between a maximum of the measured setup times and a minimum of the measured setup times may be calculated (by the controller). Then, the average setup time may (only) be calculated if the difference is no greater than a threshold.

The compensation information may be based on temperature information for the multi-IC module and/or voltage information for the multi-IC module. The controller may be configured to receive temperature information for the multi-IC module and/or voltage information for the multi-IC module for this purpose.

In embodiments, the compensation information comprises a timing shift to be applied to a clock signal associated with the respective interconnect lane. For example, the timing shift may be applied to a reference clock associated with the one or more interconnect lanes.

As noted above, the compensation information may be determined (by the controller) by calculating an average for the timing margin or eye-width parameter over the plurality of interconnect lanes. Then, the compensation information may be based on the average for the timing margin or eye-width parameter. In this case, the timing shift may be determined by subtracting the average setup time from a reference position of the reference clock (which may have been established by previous training).

A range of circuit designs and schematics are described herein. It will be appreciated that these circuit designs can be embodied in an electronic (also ‘digital’) representation (also ‘encoding’). The electronic representation may be stored in a computer readable medium, particularly of a non-transitory nature. A suitable electronic representation may include a representation for Electronic Computer-Aided Design (ECAD) software, also referred to as Electronic Design Automation (EDA) software. In this case, parts of the representation may be stored across multiple electronic documents or files, possibly including one or more libraries of the ECAD software providing details of the components of the circuit. The ECAD representation may provide instructions suitable for manufacture (also ‘fabrication’) of a circuit as represented in the design. According to the disclosure, there may be provided such an electronic representation. A method of using such an electronic representation of an electronic circuit as part of manufacturing the electronic circuit is further considered.

Thus, according to the general sense discussed above, there may additionally be considered a computer-readable encoding of a system for die or chip interconnect clock skew compensation for a multi-IC (Integrated Circuit) module. This encoding may be in accordance with any system for die or chip interconnect clock skew compensation as herein disclosed. The encoding may be provided in any form, for instance as a signal or stored on a non-transitory computer readable medium.

As discussed above, although embodiments have been described in which the setup time is the only timing parameter measured and/or used for compensation. However, it is possible to use other timing margin measurements, such as hold time. Such a measurement can be used instead of the setup time or in addition to it (for example, an average of the setup time and hold time could be used). In the seventh step 670, discussed above, the average timing parameter (hold time or combination of setup and hold time) can be used instead of the average setup time and subtracted from the reference clock position 513, Cp_ref. More generally, any timing parameter measurable in this way could be used for determining the compensation. For example, an eye width parameter could be used instead of or in addition to one or more other timing margin parameters.

Throughout this disclosure, various embodiments may be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range.

Whenever a numerical range is indicated herein, it is meant to include any cited numeral (fractional or integral) within the indicated range. The phrases “ranging/ranges between” a first indicate number and a second indicate number and “ranging/ranges from” a first indicate number “to” a second indicate number are used herein interchangeably and are meant to include the first and second indicated numbers and all the fractional and integral numerals therebetween.

In the description and claims of the disclosure, each of the words “comprise” “include” and “have”, and forms thereof, are not necessarily limited to members in a list with which the words may be associated. In addition, where there are inconsistencies between this application and any document incorporated by reference, it is hereby intended that the present application controls.

To clarify the references in this disclosure, it is noted that the use of nouns as common nouns, proper nouns, named nouns, and the/or like is not intended to imply that embodiments of the invention are limited to a single embodiment, and many configurations of the disclosed components can be used to describe some embodiments of the invention, while other configurations may be derived from these embodiments in different configurations.

In the interest of clarity, not all of the routine features of the implementations described herein are shown and described. It should, of course, be appreciated that in the development of any such actual implementation, numerous implementation-specific decisions must be made in order to achieve the developer's specific goals, such as compliance with application- and business-related constraints, and that these specific goals will vary from one implementation to another and from one developer to another. Moreover, it will be appreciated that such a development effort might be complex and time-consuming but would nevertheless be a routine undertaking of engineering for those of ordinary skill in the art having the benefit of this disclosure.

Based upon the teachings of this disclosure, it is expected that one of ordinary skill in the art will be readily able to practice the present invention. The descriptions of the various embodiments provided herein are believed to provide ample insight and details of the present invention to enable one of ordinary skill to practice the invention. Moreover, the various features and embodiments of the invention described above are specifically contemplated to be used alone as well as in various combinations.

Conventional and/or contemporary circuit design and layout tools may be used to implement the invention. The specific embodiments described herein, and in particular the various circuit arrangements, measurements and data flows, are illustrative of exemplary embodiments, and should not be viewed as limiting the invention to such specific implementation choices. Accordingly, plural instances may be provided for components described herein as a single instance.

The approach may be applied to only one interconnect lane between two dies or chips, although multiple interconnect lanes are more typical. Although clock de-skewing is advantageously applied at the transmitter die or chip, as described herein, it will be recognized that alternative configurations of a multi-IC module may apply clock de-skewing at the receiver die or chip. In any event, the clock shift to be applied by the de-skewing is determined by approaches disclosed herein. Embodiments described herein identify a clock shift as compensation information, but alternatives are possible. For example, a reference clock timing point could be the compensation information. The compensation information can be determined at the controller (as described herein), at the chip or die acting as a receiver (the first die described herein) and/or at the chip or die acting as a transmitter (the second die described herein).

While circuits and physical structures are generally presumed, it is well recognized that in modern semiconductor design and fabrication, physical structures and circuits may be embodied in computer readable descriptive form suitable for use in subsequent design, test or fabrication stages as well as in resultant fabricated semiconductor integrated circuits. Accordingly, descriptions and claims directed to traditional circuits or structures may, consistent with particular language thereof, read upon computer readable encodings (which may be termed programs) and representations of same, whether embodied in media or combined with suitable reader facilities to allow fabrication, test, or design refinement of the corresponding circuits and/or structures. Structures and functionality presented as discrete components in the exemplary configurations may be implemented as a combined structure or component. The invention is contemplated to include circuits, systems of circuits, related methods, and computer-readable (medium) encodings of such circuits, systems, and methods, all as described herein, and as defined in the appended claims. As used herein, a computer readable medium includes at least disk, tape, or other magnetic, optical, or semiconductor (e.g., flash memory cards, ROM) medium that is non-transitory.

The foregoing detailed description has described only a few of the many possible implementations of the present invention. For this reason, this detailed description is intended by way of illustration, and not by way of limitations. Variations and modifications of the embodiments disclosed herein may be made based on the description set forth herein, without departing from the scope and spirit of the invention. It is only the following claims, including all equivalents, which are intended to define the scope of this invention. In particular, even though the main embodiments are described in the context of a 3D IC, the teachings of the present invention are believed advantageous for use with other types of semiconductor IC using I/O circuitry. Moreover, the techniques described herein may also be applied to other types of circuit applications. Accordingly, other variations, modifications, additions, and improvements may fall within the scope of the invention as defined in the claims that follow.

Embodiments of the present invention may be used to fabricate, produce, and/or assemble integrated circuits and/or products based on integrated circuits.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

The flowchart and block diagrams in the figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application, or technical improvement over technologies found in the marketplace, or to enable others of ordinary skill in the art to understand the embodiments disclosed herein.

1. A method of die or chip interconnect clock skew compensation for a multi-IC (Integrated Circuit) module, the method comprising:
measuring a timing margin or eye-width parameter, during normal operation of the multi-IC module, for each of one or more interconnect lanes at a first die or chip of the multi-IC module that is receiving data and clock signals from a second die or chip of the multi-IC module, wherein the received data signal for the measuring comprises data different from data received during a training process;
determining compensation information based on the measured timing margin or eye-width parameter for each of one or more interconnect lanes; and
compensating for clock skew based on the determined compensation information.

2. The method of claim 1, further comprising:
communicating the determined compensation information from the first die or chip of the multi-IC module to the second die or chip of the multi-IC module.

3. The method of claim 1, wherein the step of measuring a timing margin or eye-width parameter for each of the one or more interconnect lanes comprises:
testing a time span for the timing margin or eye-width parameter of the respective interconnect lane; and
outputting a test fail signal for the respective interconnect lane, the test fail signal being indicative of whether the timing margin or eye-width parameter is greater than or less than the time span.

4. The method of claim 3, wherein the step of testing a time span for the timing margin or eye-width parameter of the respective interconnect lane comprises:
setting an adjustable delay-line to delay by the time span, applying the set adjustable delay-line to a signal from the respective interconnect lane to generate a delayed interconnect lane signal, sampling the delayed interconnect lane signal and the signal from the respective interconnect lane with the same clock signal and comparing the sampled delayed interconnect lane signal with the sampled signal from the respective interconnect lane, the outputted test fail signal being based on a result of the comparing.

5. The method of claim 3, wherein the steps of testing and outputting are repeated for multiple different time spans.

6. The method of claim 1, wherein the one or more interconnect lanes comprise a plurality of interconnect lanes and the step of determining compensation information is based on measured timing margins or eye-width parameters for the plurality of interconnect lanes.

7. The method of claim 6, wherein the step of determining compensation information comprises:
calculating an average for the timing margin or eye-width parameter over the plurality of interconnect lanes, the compensation information being based on the average for the timing margin or eye-width parameter.

8. The method of claim 7, wherein the average for the timing margin or eye-width parameter is calculated by taking half of the sum of a maximum of the measured timing margins or eye-width parameters and a minimum of the measured timing margins or eye-width parameters.

9. The method of claim 7, wherein the step of determining compensation information further comprises:
calculating a difference between a maximum of the measured setup times and a minimum of the measured setup times,
the step of calculating an average setup time being performed if the difference is no greater than a threshold.

10. The method of claim 1, wherein the timing margin is a setup time or a hold time.

11. The method of claim 1, wherein the step of determining compensation information is based on temperature information for the multi-IC module and/or voltage information for the multi-IC module.

12. The method of claim 1, wherein the compensation information comprises a timing shift to be applied to a clock signal associated with the respective interconnect lane.

13. The method of claim 11, wherein the timing shift is applied to a reference clock associated with the one or more interconnect lanes.

14. The method of claim 12, wherein the step of determining compensation information comprises:
calculating an average for the timing margin or eye-width parameter over the plurality of interconnect lanes, the compensation information being based on the average for the timing margin or eye-width parameter,
the timing shift being determined by subtracting the average setup time from a reference position of the reference clock.

15. A system for die or chip interconnect clock skew compensation for a multi-IC (Integrated Circuit) module, the system comprising:
at least one Input/Output (I/O) sensor, each I/O sensor being configured to measure a respective one of one or more interconnect lanes at a first die or chip of the multi-IC module that is receiving data and clock signals from a second die or chip of the multi-IC module;
a controller, configured to determine a respective timing margin or eye-width parameter, during normal operation of the multi-IC module, for each of the one or more interconnect lanes based on the measurement of the respective I/O sensor and to determine compensation information to compensate for clock skew based on the timing margin or eye-width parameter for each of the one or more interconnect lanes, wherein the received data signal for the measuring comprises data different from data received during a training process.

16. The system of claim 15, wherein the controller is further configured to communicate the determined compensation information from to the second die or chip of the multi-IC module, such that compensation for clock skew can be performed at the second die or chip of the multi-IC module, based on the determined compensation information.

17. The system of claim 15, wherein each I/O sensor is configured to measure the respective one of the one or more interconnect lanes by:
testing a time span for the timing margin or eye-width parameter of the respective interconnect lane; and
outputting a test fail signal for the respective interconnect lane, the test fail signal being indicative of whether the timing margin or eye-width parameter is greater than or less than the time span.

18. The system of claim 17, wherein each I/O sensor comprises:
an adjustable delay-line, configured to apply the time span to a signal from the respective interconnect lane to generate a delayed interconnect lane signal;
at least one state element, configured to sample the delayed interconnect lane signal and the signal from the respective interconnect lane with the same clock signal; and
a comparison circuit, configured to compare the sampled delayed interconnect lane signal with the sampled signal from the respective interconnect lane and output the test fail signal based on a result of the comparing.

19. The system of claim 17, wherein the controller is configured to cause each I/O sensor to repeat the testing and outputting for multiple different time spans in order to determine the respective timing margin or eye-width parameter for each of the one or more interconnect lanes.

20. The system of claim 15, wherein the one or more interconnect lanes comprise a plurality of interconnect lanes and the controller is configured to determine the compensation information based on the timing margins or eye-width parameters for the plurality of interconnect lanes.

21. The system of claim 20, wherein the controller is configured to determine the compensation information by calculating an average for the timing margin or eye-width parameter over the plurality of interconnect lanes, the compensation information being based on the average for the timing margin or eye-width parameter.

22. The system of claim 21, wherein the controller is configured to calculate the average for the timing margin or eye-width parameter by taking half of the sum of a maximum of the measured timing margins or eye-width parameters and a minimum of the measured timing margins or eye-width parameters.

23. The system of claim 21, wherein the controller is configured to determine the compensation information by calculating a difference between a maximum of the measured timing margins or eye-width parameters and a minimum of the measured timing margins or eye-width parameters, the average for the timing margin or eye-width parameter being calculated if the difference is no greater than a threshold.

24. The system of claim 15, wherein the controller is configured to receive temperature information for the multi-IC module and/or voltage information for the multi-IC module and to determine the compensation information based on the received temperature information and/or the received voltage information.

25. The system of claim 15, wherein the controller is configured to determine the compensation information as a timing shift to be applied to a clock signal associated with the respective interconnect lane.

26. The system of claim 25, wherein the controller is configured to determine the timing shift to be applied to a reference clock associated with the respective interconnect lane.

27. The system of claim 26, wherein the controller is further configured to determine the compensation information by calculating an average for the timing margin or eye-width parameter over the plurality of interconnect lanes, the compensation information being based on the average for the timing margin or eye-width parameter, the timing shift being determined by subtracting the average for the timing margin or eye-width parameter from a reference position of the reference clock.

28. A multi-IC (Integrated Circuit) module comprising:
a first die or chip, configured to receive data and clock signals over one or more interconnect lanes;
a second die or chip, configured to transmit the data and clock signals over the one or more interconnect lanes to the first die or chip;
a system for die or chip interconnect clock skew compensation according to claim 15, coupled to the first die or chip and configured to compensate for clock skew in the clock signals.

29. A non-transitory computer readable medium having stored thereon a computer-readable encoding of a system for die or chip interconnect clock skew compensation for a multi-IC (Integrated Circuit) module, the system comprising:
at least one Input/Output (I/O) sensor, each I/O sensor being configured to measure a respective one of one or more interconnect lanes at a first die or chip of the multi-IC module that is receiving data and clock signals from a second die or chip of the multi-IC module;
a controller, configured to determine a respective timing margin or eye-width parameter, during normal operation of the multi-IC module, for each of the one or more interconnect lanes based on the measurement of the respective I/O sensor and to determine compensation information to compensate for clock skew based on the timing margin or eye-width parameter for each of the one or more interconnect lanes, wherein the received data signal for the measuring comprises data different from data received during a training process.
